(19) United States
(12) Patent Application Publication
(10) Pub. No.: US 2014/0120373 A1
(43) Pub. Date: May 1, 2014

(54) METHOD OF NUCLEATING THE GROWTH A DIAMOND FILM AND A DIAMOND FILM NUCLEATED THEREOF

(71) Applicant: NATIONAL CHIAO TUNG UNIVERSITY, Hsinchu City (TW)

(72) Inventors: Li CHANG, Hsinchu City (TW); Yi-Chun CHEN, Kaohsiung City (TW)

(73) Assignee: NATIONAL CHIAO TUNG UNIVERSITY, Hsinchu City (TW)

(21) Appl. No.: 13/727,998

(22) Filed: Dec. 27, 2012

(30) Foreign Application Priority Data
Oct. 26, 2012 (TW) 101139688

(51) Int. Cl. C30B 25/18; C30B 29/04

(52) U.S. Cl. CPC C30B 25/18; C30B 29/04
USPC 428/688; 117/103

(57) ABSTRACT

A method of nucleating the growth a diamond film comprises the following steps. First, a substrate is provided upon which the diamond film is to be nucleated. A diamondoid is then dissolved in an adhesive solvent to form a mixing solution. The substrate is inserted into the mixing solution to let the diamondoid attach to the substrate through the adhesive solvent. A diamond film nucleated by the abovementioned method is also disclosed in the present invention.

### BACKGROUND OF THE INVENTION

1. Field of the Invention

This invention relates to a method of nucleating the growth a diamond film, and particularly to a method of nucleating the growth a diamond film by incorporating a diamondoid with an adhesive solvent.

2. Description of the Prior Art

Diamond has a variety of outstanding properties, such as wide band gap, chemical inertness, high carrier mobility, excellent biological compatibility, high propagation speed of acoustic wave, good optical transparency, high thermal conductivity, and the greatest hardness, which make it a promising candidate for a wide range of application, for instance, microelectronics, optics, tribological, thermal management, biomedical, DNA-based sensors, manufacturing engineering, and so on.

Recently, it is found that the nucleation is a key procedure of growing a diamond film. Therefore, there are many methods studied for synthesizing the diamond film and increasing the density of the nucleation, such as scratching, ion-beam-assisted deposition and bias enhanced nucleation. However, the scratching will damage the surface of the substrate hardly and the diamond film grown thereon cannot be applied with an electronic device. The Ion-beam-assisted deposition will produce the non-crystallized carbon and the nano diamond particle at the same time. It may also form the diamond crystal in the non-crystal carbon layer. It may cause the bad crystal direction between diamond and the substrate, thus it cannot offer a good diamond film with the good orientation for electronic devise. As to the bias enhanced nucleation, it is not suitable for the requirement of highly rough surface although it will damage the surface of the substrate but not as much as the scratching. The carbon process is still necessary before nucleating by bias enhancing which will increase the time of diamond synthesized. Another disadvantage of the bias enhanced nucleation is a conductive substrate is necessary. Otherwise the nucleation will not be progress.

### SUMMARY OF THE INVENTION

Adamantane (C₁₀H₁₆) is one of a series of carbon structure, a very stable crystalline compound, and a highly symmetric molecule with point group symmetry, Td. Furthermore, Adamantane is the smallest possible diamondoid (the chemical formula is C (4n+6) H (4n+12), where n=0, 1, 2, 3 . . . ), consisting of 10 carbon atoms arranged as a single diamond cage surrounded by 16 hydrogen atoms. Therefore, a diamondoid such as adamantane and its derivatives can be used as nuclei for nucleating the diamond film in the present invention.

It is an object of the present invention to provide a method of nucleating the growth a diamond film. The method comprises the following steps: First, a substrate is provided upon which the diamond film is to be nucleated. A diamondoid is then dissolved in an adhesive solvent to form a mixing solution. The substrate is inserted into the mixing solution to let the diamondoid attach to the substrate through the adhesive solvent.

In the preferred embodiment of the invention, the adhesive solvent is ethylene glycol or diethylene glycol.

In the preferred embodiment of the invention, the diamondoid is selected from the group consisting of adamantane, diamantane, triamantane, tetramantane, pentamantane, cyclohexamantane, decamantane, isomers and derivatives thereof.

In the preferred embodiment of the invention, the step of inserting the substrate into the mixing solution is performed by a dip coating process.

In the preferred embodiment of the invention, the method disclosed in the present invention for nucleating the growth the diamond film further comprising the following steps: First, a reactor is provided and the reactor has an enclosed process space. The substrate is positioned within the reactor to be grown the diamond film thereon. According to a preferred embodiment, the reactor is configured to carry out a microwave plasma chemical vapor deposition technique.

In the preferred embodiment of the invention, the ratio of the weight percent between the adhesive solvent and the diamondoid is from 10 to 100.

In the preferred embodiment of the invention, the substrate is selected from the group consisting of Si, MN, TiN, GaN, TiC and sapphire.

It is another object of the present invention to provide a diamond film nucleated by the abovementioned method. In the preferred embodiment of the invention, the adhesive solvent is ethylene glycol or diethylene glycol. In the preferred embodiment of the invention, the diamondoid is selected from the group consisting of adamantane, diamantane, triamantane, tetramantane, pentamantane, cyclohexamantane, decamantane, isomers and derivatives thereof.

The features and advantages of the present invention will be understood and illustrated in the following specification and FIG. 1A, FIG. 1B, FIG. 1C, FIG. 2A, FIG. 2B, FIG. 2C, FIG. 3A, FIG. 3B and FIG. 3C.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1A, FIG. 1B and FIG. 1C are schematic views showing a method of nucleating the growth a diamond film on a substrate in accordance with a preferred embodiment of the present invention.

FIG. 2A is a schematic view of showing a low resolution image of the diamond film growth on the substrate in accordance with a first embodiment of the present invention.

FIG. 2B is a schematic view of showing a high resolution image of the diamond film growth on the substrate in accordance with the first embodiment of the present invention.

FIG. 2C is a schematic view of showing Raman spectra of the diamond film growth on the substrate in accordance with the first embodiment of the present invention.

FIG. 3A is a schematic view of showing a low resolution image of the diamond film growth on the substrate in accordance with a second embodiment of the present invention.

FIG. 3B is a schematic view of showing a high resolution image of the diamond film growth on the substrate in accordance with the second embodiment of the present invention.

FIG. 3C is a schematic view of showing Raman spectra of the diamond film growth on the substrate in accordance with the second embodiment of the present invention.

### DESCRIPTION OF THE PREFERRED EMBODIMENT

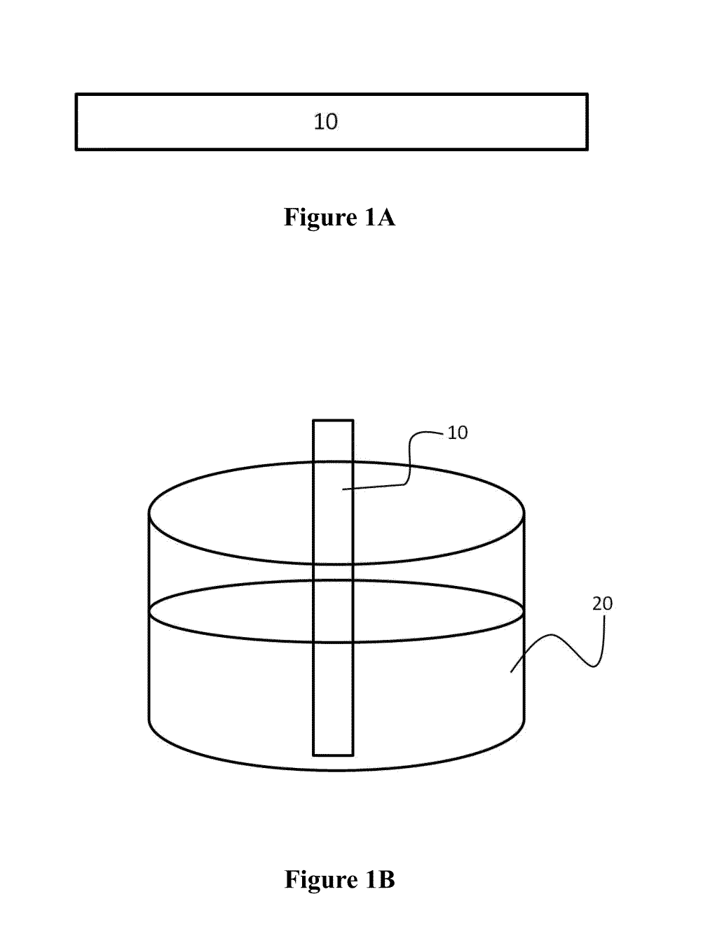

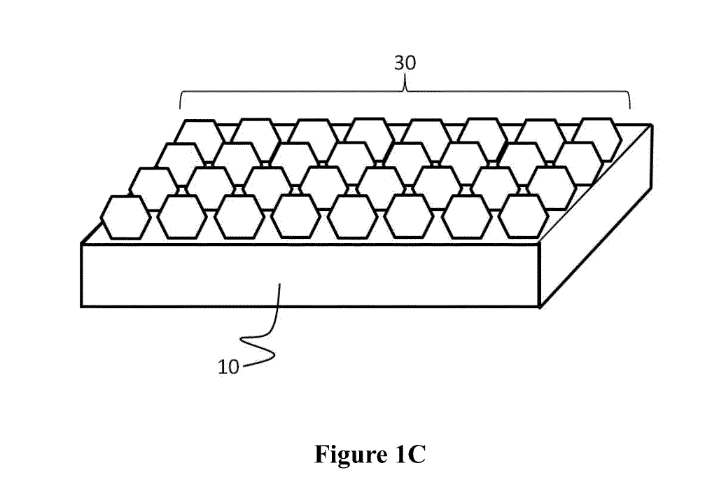

Please refer to FIG. 1A, FIG. 1B and FIG. 1C. FIG. 1A, FIG. 1B and FIG. 1C are schematic views showing a method of nucleating the growth a diamond film on a substrate in accordance with a preferred embodiment of the present invention. As shown in FIG. 1A, the substrate 10 is provided upon which the diamond film is to be nucleated. In the preferred embodiment of the invention, the substrate is selected from the group consisting of Si, MN, TiN, GaN, TiC and sapphire. That is, the selectivity of the substrate 10 does not need to be limited on a conductive substrate by using the method provided in the present invention.

As shown in FIG. 1B, a diamondoid is then dissolved in an adhesive solvent to form a mixing solution 20, and the substrate 10 is then inserted into the mixing solution 20 to process a dip coating process. In the preferred embodiment of the invention, the ratio of the weight percent between the adhesive solvent and the diamondoid is from 10 to 100. For example, it can be performed by adding 0.1 g adamantane into 0.1 ml adhesive solvent, or adding 1 g adamantane into 0.1 ml adhesive solvent. The present invention is not limited thereto.

In the preferred embodiment of the invention, the diamondoid is selected from the group consisting of adamantane, diamantane, triamantane, tetramantane, pentamantane, cyclohexamantane, decamantane, isomers and derivatives thereof. Furthermore, the adhesive solvent is ethylene glycol in accordance with a first embodiment of the present invention, and diethylene glycol in accordance with a second embodiment of the present invention. However, the adhesive solvent will not limited to the abovementioned two embodiments and can be other solvent with viscosity.

As shown in FIG. 1C, the diamondoids 30 will then attach to the substrate 10 through the adhesive solvent. That is, the diamondoids 30 can be attached to the substrate 10 without damaging the substrate 10, and the diamondoids 30 are served as nuclei for the following growing steps. In a preferred embodiment, a reactor will be provided and the reactor has an enclosed process space. The substrate 10 is then positioned within the reactor to be grown the diamond film thereon.

According to the preferred embodiment, the reactor is configured to carry out a microwave plasma chemical vapor deposition technique. In the preferred embodiment of the invention, the step of growing the diamond film on the substrate is performed at a temperature from 500 to 1000 degrees C.

According to the preferred embodiment, the step of growing the diamond film on the substrate as abovementioned further comprises a step of introducing a process gas into the process space. In the preferred embodiment of the invention, the process gas is composed of H₂ and CH₄, the mixing ratio of H₂ and CH₄ is from 0.1% to 10%.

According to the preferred embodiment, the step of growing the diamond film on the substrate takes from 0.5 hour to 2 hours, and 1 hour is more preferred. Furthermore, other conditions of the microwave plasma chemical vapor deposition are also provided as the following: for example, a microwave power is from 500 W to 3000 W, a flow rate of the process gas is from 100 to 1000 sccm and so on. However, the present invention is not limited thereto.

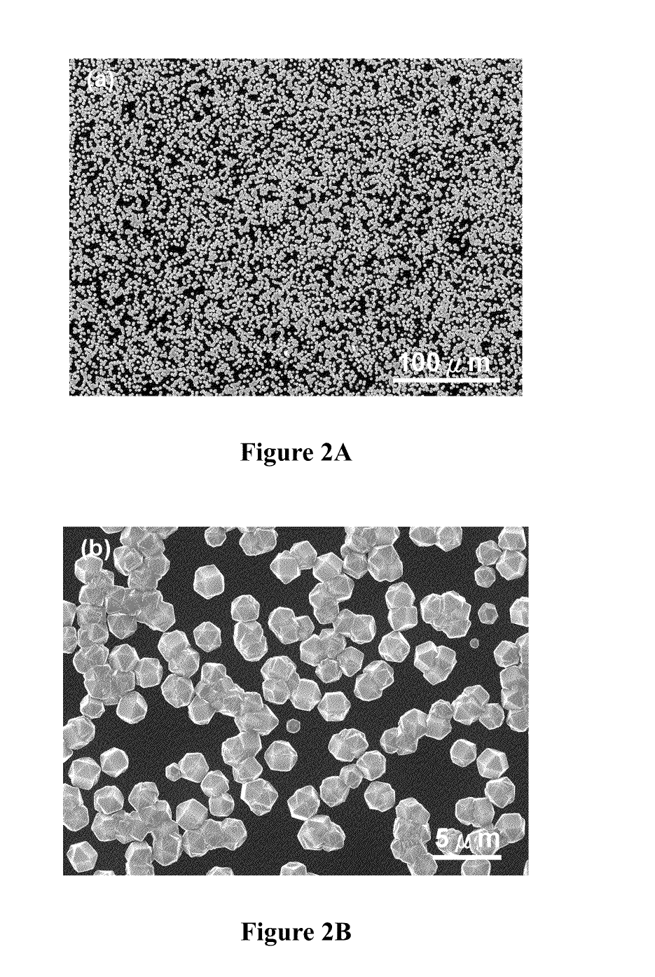

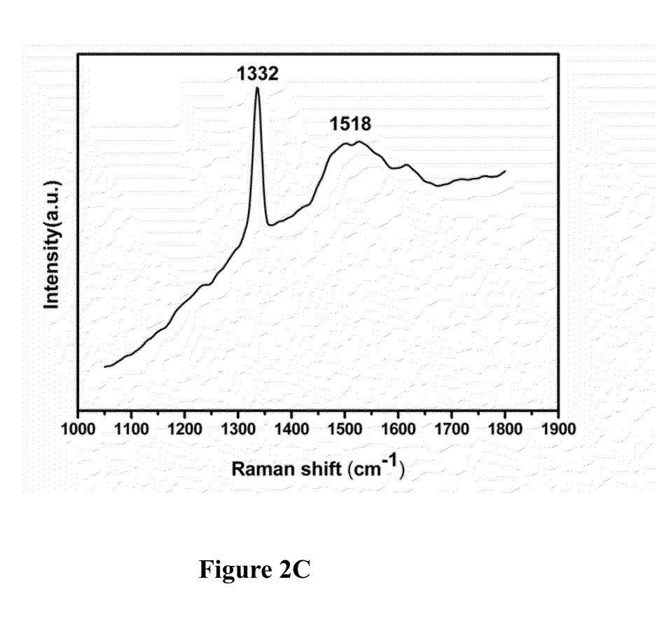

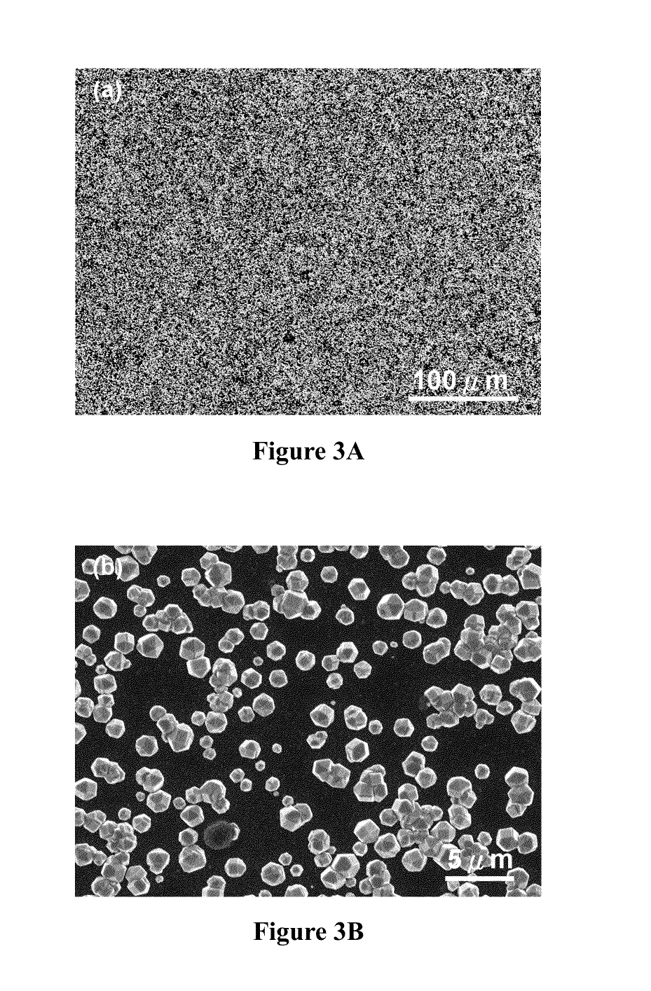

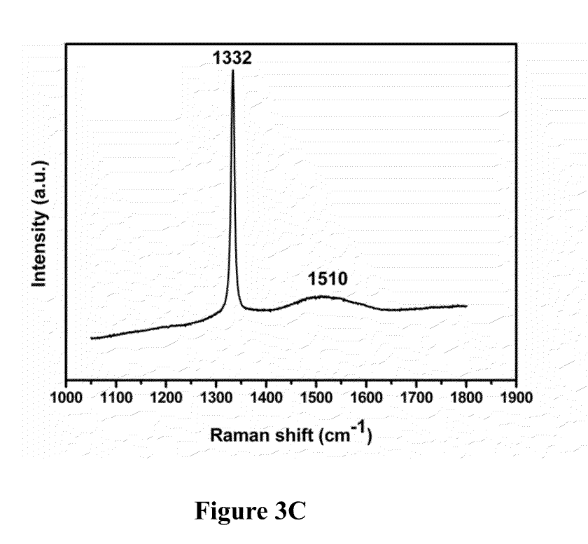

Please refer to FIG. 2A, FIG. 2B and FIG. 2C and FIG. 3A, FIG. 3B and FIG. 3C, FIG. 2A and FIG. 3A are schematic views of showing a low resolution image of the diamond film growth on the substrate in accordance with the first embodiment and the second embodiment of the present invention, FIG. 2B and FIG. 3B are schematic views of showing a high resolution image of the diamond film growth on the substrate in accordance with the first embodiment and the second embodiment of the present invention, and FIG. 2C and FIG. 3C is schematic views of showing a Raman spectra of the diamond film growth on the substrate in accordance with the first embodiment and the second embodiment of the present invention.

As shown in FIG. 2A and FIG. 3A, it is clearly shown that the diamondoid will be successively attached to the substrate with a density of 3.4×10⁻⁸ cm⁻¹, the growth rate is about 1-2 (μm/per hour, i.e., the growth rate is quite fast than before. And then, it is also clearly shown that the diamondoids grown on the substrate have a diamond shape.

FIG. 2C and FIG. 3C exhibits typical Raman spectra of the diamond film grown on the substrate using the adamantane as nuclei. In the spectra, the peak of the diamond film around 1332 cm⁻ is obvious.

That is, the adhesive solvent such as ethylene glycol or diethylene glycol is helpful for enhancing the attaching efficiency of the adamantane.

To sum up, the method disclosed in the present invention for nucleating the growth the diamond film on the substrate will not damage the substrate and will not take a long time for nucleating. And then, the step of nucleating is performed by a dip coating process and can be more effective, simple and suitable for applied on a substrate with a larger area.

The description of the invention and its applications as set forth herein is illustrative and is not intended to limit the scope of the invention. Variations and modifications of the embodiments disclosed herein are possible and practical alternatives to and equivalents of the various elements of the embodiments would be understood to those of ordinary skill in the art upon study of this patent document. These and other variations and modifications of the embodiments disclosed herein may be made without departing from the scope and spirit of the invention.

It is understood that various other modifications will be apparent to and can be readily made by those skilled in the art without departing from the scope and spirit of this invention. Accordingly, it is not intended that the scope of the claims appended hereto be limited to the description as set forth herein, but rather that the claims be construed as encompassing all the features of patentable novelty that reside in the present invention, including all features that would be treated as equivalents thereof by those skilled in the art to which this invention pertains.

What is claimed is:

1. A method of nucleating the growth a diamond film, comprising:
providing a substrate upon which the diamond film being to be nucleated;
dissolving a diamondoid in an adhesive solvent to form a mixing solution;
inserting the substrate into the mixing solution, wherein the diamondoid being attached to the substrate through the adhesive solvent;
providing a reactor having an enclosed process space, wherein the reactor is configured to carry out a microwave plasma chemical vapor deposition technique;
positioning the substrate within the reactor; and
growing the diamond film on the substrate.

2. The method of nucleating the growth the diamond film according to claim 1, wherein the adhesive solvent is selected from the group consisting of ethylene glycol and diethylene glycol.

3. The method of nucleating the growth the diamond film according to claim 1, wherein the diamondoid is selected from the group consisting of adamantane, diamantane, triamantane, tetramantane, pentamantane, cyclohexamantane, decamantane, isomers and derivatives thereof.

4. The method of nucleating the growth the diamond film according to claim 1, wherein the step of inserting the substrate into the mixing solution is performed by a dip coating process.

5. The method of nucleating the growth the diamond film according to claim 1, wherein the ratio of the weight percent between the adhesive solvent and the diamondoid is from 10 to 100.

6. The method of nucleating the growth the diamond film according to claim 1, wherein the substrate is selected from the group consisting of Si, MN, TiN, GaN, TiC and sapphire.

7. A diamond film nucleated by the steps comprising:
providing a substrate upon which the diamond film being to be nucleated;
dissolving a diamondoid in an adhesive solvent to form a mixing solution; and
inserting the substrate into the mixing solution;
wherein the diamondoid is attached to the substrate through the adhesive solvent.

8. The diamond film according to claim 7, wherein the adhesive solvent is selected from the group consisting of ethylene glycol and diethylene glycol.

9. The diamond film according to claim 7, wherein the diamondoid is selected from the group consisting of adamantane, diamantane, triamantane, tetramantane, pentamantane, cyclohexamantane, decamantane, isomers and derivatives thereof.

10. The diamond film according to claim 7, wherein the step of inserting the substrate into the mixing solution is performed by a dip coating process.
